(19) United States
(12) Patent Application Publication
(10) Pub. No.: US 2008/0204619 A1
(43) Pub. Date: Aug. 28, 2008

(54) Display device

(75) Inventors: Terunori Saitou, Mobara (JP); Yoshiharu Owaku, Mobara (JP); Kozo Yasuda, Mobara (JP); Toshio Miyazawa, Chiba (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/071,342

(22) Filed: Feb. 20, 2008

(30) Foreign Application Priority Data
Feb. 22, 2007 (JP) 2007-042529

(51) Int. Cl. G02F 1/1343; H01L 27/02; H01J 1/62

(52) U.S. Cl. 349/43; 257/59; 313/498; 257/E27.009

(57) ABSTRACT

A display device in which gate drive circuits are formed at both sides of an effective screen, and a static charge shield conductive film is formed to cover the gate drive circuits. In the manufacturing step and after producing the display device, the constant voltage is applied to the static charge shield conductive film via the common pad, the earth connection line and the like.

### CLAIM OF PRIORITY

The present application claims priority from Japanese Application JP 2007-042529 filed on Feb. 22, 2007, the content of which is hereby incorporated by reference into this application.

### BACKGROUND OF THE INVENTION

1. Field of the Invention:

The present invention relates to a display device of active matrix type, for example, a liquid crystal display device, an organic EL display device and the like, and particularly to a display device having a drive circuit integrally formed with a display panel.

2. Description of the Related Art:

The liquid crystal display device has been increasingly demanded for the use in various fields. Generally the liquid crystal display device has a large number of pixels arranged in a matrix state defined by laterally arranged data signal lines each extending in the longitudinal direction, and longitudinally arranged scanning lines each extending in the lateral direction. The input of the image signal to each pixel is switched by a thin film transistor (TFT) formed in the pixel. The data signal line and the scanning signal line are driven by a data driver circuit and a gate driver circuit, respectively.

In the case where the TFT using a-Si is provided in the pixel, the IC chip is externally provided as the gate driver and the data driver. Meanwhile, the process for forming the TFT using the polysilicon has been put into the practical use for the relatively small sized liquid crystal display device. Because of the high mobility of the electron or the hole in the polysilicon, the gate driver and the data driver may be mounted around the effective screen by the use of the TFT.

If the driver circuit is mounted on the liquid crystal substrate with the TFT, the space may be considerably saved. If the TFT for the driver circuit is produced simultaneously with formation of the TFT for the pixel, the manufacturing cost may be reduced. Japanese Unexamined Patent Application Publication No. 2002-175056 discloses the technique for mounting not only the driver circuit but also the memory circuit on the liquid crystal substrate at the portion around the screen with the TFT. In the patent document, the memory circuit is formed around the screen, and the conductive film is disposed on the memory circuit via the insulation film so as to form the auxiliary capacitance.

Japanese Unexamined Patent Application Publication No. 2002-156653 discloses the technique for forming the drive circuit around the effective screen with the TFT so as to be covered with the light shielding film. In the aforementioned technique, the member for sealing the liquid crystal which is formed of the light curing resin is employed so as to be sealed through light irradiation from above the counter substrate. As a result, the black frame is formed around the screen, which allows the use of the light curing resin as the sealing member produced in the simple manufacturing step.

However, formation of the drive circuit on the liquid crystal substrate outside the effective screen with the TFT may have the disadvantage in the course of the liquid crystal manufacturing process. The liquid crystal manufacturing process includes the step which causes static charge, for example, the step for rubbing the orientation film. As the rubbing step is performed after the formation of the TFT for the drive circuit, the resultant static charge may destroy the TFT for the drive circuit.

Another disadvantage is the malfunction of the drive circuit owing to the external noise in the manufacturing process or the timing after the manufacturing of the product is finished. The increase in the threshold voltage Vth of the TFT may be considered for avoiding the aforementioned malfunction. However, the increase in the Vth may interfere with the high-speed driving operation.

### SUMMARY OF THE INVENTION

It is an object of the present invention to prevent the driver circuit formed around the screen with the TFT from being destroyed by the static charge, and the malfunction of the driver circuit due to the external noise. The specific structures to realize the aforementioned object will be described as follows.
(1) According to an aspect of the present invention, in a display device, a thin film transistor and a pixel portion including a pixel electrode are arranged in a matrix state on an image forming portion of a substrate, and a gate driver circuit including the thin film transistor is formed on the substrate outside the image forming portion. Metal oxide conductive films which interpose an insulation member are formed on the gate driver circuit, and a constant voltage is applied to the metal oxide conductive films. In the aforementioned structure, the gate driver circuit is formed with the TFT outside the effective screen such that the gate driver is covered with the static charge shield conductive film. This makes it possible to prevent the risk of causing the malfunction of the gate driver circuit by the noise during the operation of the liquid crystal display device. The use of the static charge shield conductive film does not require the increase in the threshold voltage of the TFT, thus enabling the high-speed operation.
(2) In the display device, the metal oxide conductive film is formed simultaneously with a formation of the pixel electrode. In the aforementioned structure, the static charge shield conductive film may be formed simultaneously with formation of the pixel electrode, thus suppressing the cost increase.
(3) In the display device, the metal oxide conductive film is formed of an ITO. In the aforementioned structure, the static charge shield conductive film is formed of the ITO which has been widely used as the metal oxide conductive film, thus improving the reliability and suppressing the cost increase.
(4) In the display device, the gate driver circuits are formed at both sides of the image forming portion. In the aforementioned structure, the gate driver circuits are formed at both sides of the effective screen. This makes it possible to suppress the increase in the size of the gate circuit at one side, and to easily form the circuit structure with the TFT.
(5) In the display device, the metal oxide conductive film partially extends to an end portion of the substrate. In the aforementioned structure, the static charge shield conductive film extends to the end surface of the substrate, thus allowing the easy protection from the static charge and the like in the middle of the step for forming the substrate of the display device.
(6) According to another aspect of the present invention, in a display device, a thin film transistor and a pixel portion including a pixel electrode are arranged in a matrix state on an image forming portion of a substrate, and a gate driver circuit including the thin film transistor and a data driver circuit including the thin film transistor are formed on the substrate outside the image forming portion. Metal oxide conductive films which interpose an insulation member are formed on the gate driver circuit and the data driver circuit, and a constant voltage is applied to the metal oxide conductive films.
(7) In the display device, the metal oxide conductive film partially extends to an end portion of the substrate. In the aforementioned structure, the data driver circuit is also formed on the substrate with the TFT, thus further reducing the size of the display device and improving the reliability thereof.
(8) According to another aspect of the present invention, in a liquid crystal display device, a thin film transistor and a pixel portion including a pixel electrode are arranged in a matrix state on an image forming portion of a TFT substrate, a gate driver circuit including the thin film transistor is formed on the TFT substrate outside the image forming portion, and a counter substrate with an electrode to which a common voltage is applied is sealed with the TFT substrate using a sealing member outside the image forming portion. Metal oxide conductive films which interpose an insulation member are formed on the gate driver circuit, and the common voltage is applied to the metal oxide conductive films. In the aforementioned structure, the gate driver circuit is formed on the TFT substrate of the liquid crystal display device so as to cover the gate driver circuit with the static charge shield conductive film to which the common voltage is applied. This makes it possible to stably operate the gate driver circuit formed with the TFT to perform the high-speed operation.
(9) In the liquid crystal display device, the metal oxide conductive film is conducted with an electrode formed on the counter substrate, to which the common voltage is applied. In the aforementioned structure, the common voltage may be easily supplied to the static charge shield conductive film through conduction with the common electrode of the color filter substrate.
(10) In the liquid crystal display device, the metal oxide conductive film partially extends to an end portion of the TFT substrate. In the aforementioned structure, the static charge shield conductive film is formed to reach the end portion of the TFT substrate. This makes it possible to easily supply the specific potential to the static shield conductive film in the middle of the manufacturing step.
(11) In the liquid crystal display device, the TFT substrate is formed by cutting a base plate which is larger than the TFT substrate in a manufacturing step. The metal oxide conductive film partially extends to the base plate passing the end portion of the TFT substrate before cutting thereof. A constant potential is applied to the metal oxide conductive film in the manufacturing step. In the aforementioned structure, the specific potential is applied to the static charge shield conductive film in the middle of the step for manufacturing the liquid crystal display device. This makes it possible to prevent the driver circuit formed with the TFT from being destroyed by the static charge in the middle of the step for manufacturing the liquid crystal display device.
(12) In the liquid crystal display device, the constant voltage is an earth potential. In the aforementioned structure, the earth potential is applied to the static charge shield conductive film in the middle of the step for manufacturing the liquid crystal display device. This makes it possible to prevent the driver circuit formed with the TFT from being destroyed-by the static charge and the like in the middle of the step for manufacturing the liquid crystal display device.
(13) In the liquid crystal display device, an organic resin film is formed between a source/drain electrode of the thin film transistor and the metal oxide conductive film. In the aforementioned structure, the organic resin film with large thickness and low permittivity is formed between the drive circuit formed with the TFT and the static charge shield conductive film. This ensures the insulation reliability, and suppression of the increase in the floating capacitance.
(14) According to another aspect of the present invention, in a liquid crystal display device, a thin film transistor and a pixel portion including a pixel electrode are arranged in a matrix state on an image forming portion of a TFT substrate, a gate driver circuit including the thin film transistor and a data driver circuit including the thin film transistor are formed on the TFT substrate outside the image forming portion, and a counter substrate with an electrode to which a common voltage is applied is sealed with the TFT substrate using a sealing member outside the image forming portion. Metal oxide conductive films which interpose an insulation member are formed on the gate driver circuit and the data driver circuit, and the common voltage is applied to the metal oxide conductive films.
(15) In the liquid crystal display device, the metal oxide conductive film partially extends to an end portion of the TFT substrate. In the aforementioned structure, as the data driver circuit is also formed on the substrate with the TFT, the size of the liquid crystal display device may further be reduced, and the reliability of the liquid crystal display device may be improved.
(16) According to another aspect of the present invention, in an organic EL display device, a thin film transistor and a pixel portion including an organic EL light emission portion are arranged in a matrix state on an image forming portion of a substrate, and a gate driver circuit including the thin film transistor is formed on the substrate outside the image forming portion. Metal oxide conductive films which interpose an insulation member are formed on the gate driver circuit, and a constant voltage is applied to the metal oxide conductive films. In the aforementioned structure, the gate driver circuit is formed on the substrate of the organic EL display device such that the gate drive circuit is covered with the static charge shield conductive film to which the constant voltage is applied. This makes it possible to stably operate the gate driver circuit formed with the TFT, and ensures the high-speed operation.
(17) In the organic EL display device, the organic EL display device is of a bottom emission type. The organic EL light emission portion is formed of a lower electrode, an organic EL film, and an upper electrode. The metal oxide conductive film is formed through a same process as that for forming the lower electrode. In the organic EL display device of bottom emission type, as the conductive film which is the same as the one for forming the lower electrode is used for forming the static charge shield conductive film, the cost increase for realizing the present invention may be suppressed besides the effect as described above.
(18) In the organic EL display device, the organic EL display device is of a top emission type. The organic EL light emission portion is formed of the lower electrode, the organic EL film, and the upper electrode. The metal oxide conductive film is formed through a same process as that for forming the upper electrode. In the organic EL display device of top emission type, as the conductive film which is the same as the one for forming the upper electrode is used for forming the static charge shield conductive film, the cost increase for realizing the present invention may be suppressed besides the effect as described above.
(19) In the organic EL display device, the insulation member includes an organic resin film. In the organic EL display device, the organic resin film with the large thickness and low permittivity may be formed between the driver circuit formed with the TFT and the static charge shield conductive film. This ensures the insulation reliability and suppresses the increase in the floating capacitance.
(20) In the organic EL display device, the insulation member includes an organic resin film with a double-layer structure. In the organic EL display device of top emission type, two-layered organic resin film is formed between the driver circuit formed with the TFT and the static charge shield conductive film. This makes it possible to further improve the insulation reliability and further to reduce the floating capacitance.

### BRIEF DESCRIPTION OF THE DRAWINGS

FIG. 1 is a view showing the structure of a liquid crystal display device according to a first embodiment.

FIG. 2 is a sectional view of the liquid crystal display device.

FIG. 3 is a sectional view of a pixel portion of the liquid crystal display device.

FIG. 4 is a sectional view of a TFT portion of a gate driver circuit.

FIG. 5 is a plan view schematically showing the first embodiment.

FIG. 6 is a plan view schematically showing a state in the middle of the step according to the first embodiment.

FIG. 7 is a view showing the structure of a liquid crystal display device according to a second embodiment. FIG. 8 is a plan view schematically showing the second embodiment.

FIG. 9 is a plan view schematically showing a state in the middle of the step according to the second embodiment.

FIG. 10 is a view illustrating the principle of the field sequential mode.

FIG. 11 is a view illustrating the operation of the field sequential mode.

FIG. 12 is a plan view of an organic EL display device.

FIG. 13 is a sectional view of the organic EL display device of bottom emission type.

FIG. 14 is a sectional view of the organic EL display device of top emission type.

FIG. 15 is a sectional view of the TFT portion in the gate driver circuit according to a fourth embodiment.

### DESCRIPTION OF THE PREFERRED EMBODIMENTS

Embodiments according to the present invention will be described in detail hereinafter.

### First Embodiment

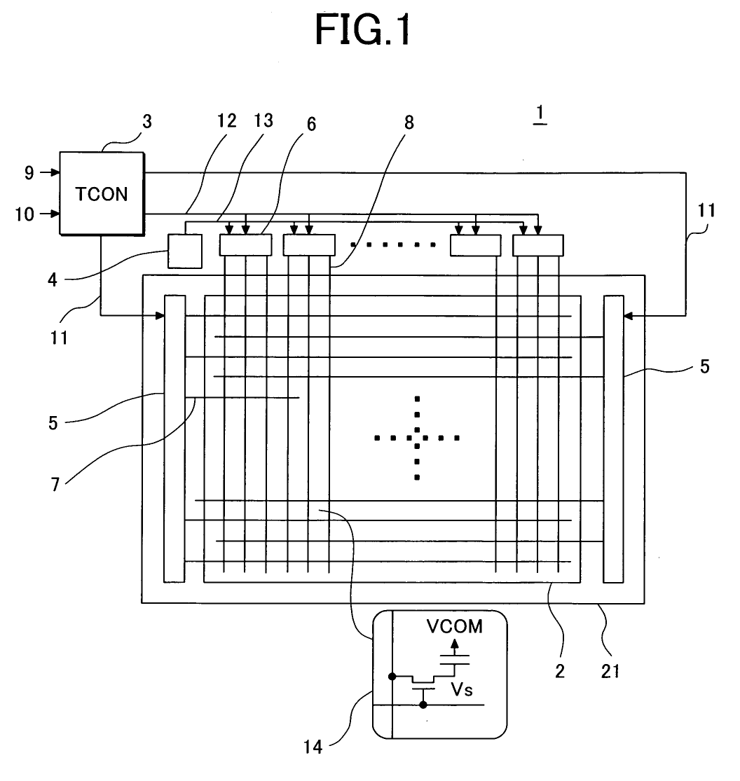

FIG. 1 schematically shows the structure of a liquid crystal display device 1 according to a first embodiment. Referring to FIG. 1, an effective screen 2 for forming the image occupies major part of the structure of the liquid crystal display device 1. Input display data 9 and an input signal set 10 are transferred to the liquid crystal display device 1 from a host such as a cell phone and a computer so as to be input to a control IC 3. A gate driver control signal set 11 is output from the control IC 3 to a gate driver circuit 5. The gate driver circuit 5 is mounted on a TFT substrate 21 with the TFT. The gate driver control signal set 11 includes a shift signal which defines the scanning period for a single line, and a start signal which defines the start of scanning the head line. Scanning signal lines 7 extend from the left and right gate driver circuits 5 formed at both sides of the screen alternately on the effective screen 2.

A data driver control signal set 12 is output to the data driver IC 6 from the control IC 3. The data driver control signal set 12 includes the display data, the output signal which defines the output timing of the tone voltage based on the display data, the alternating current signal which determines the polarity of the source voltage, and a clock signal in synchronization with the display data. A tone voltage 13 is output to the data driver from a tone voltage generation circuit 4. The data driver IC 6 selects the tone voltage 13 output from the tone voltage generation circuit 4 based on the data driver control signal to output the image display voltage to a data signal line 8 at an appropriate timing. The data driver circuit has a relatively large size compared with that of the gate driver circuit 5, which is formed in the externally provided data driver IC 6. Plural the IC chips 6 are disposed on the TFT substrate 21.

Each of pixels 14 in the portion enclosed by scanning signal lines 7 and data signal lines 8 within the effective screen area is formed of the TFT including the source electrode, the gate electrode and the drain electrode, the liquid crystal layer, and the counter electrode. As the scanning signal is applied to the gate electrode, the TFT is switched between On and Off state. In the open state of the TFT, the data voltage is written on the source electrode connected to one of the liquid crystal layers via the drain electrode. In the close state, the voltage written in the source electrode is maintained. Assuming that the voltage written into the source electrode is set to Vs, and the voltage of the counter electrode is set to Vcom, the liquid crystal layer changes the polarizing direction based on the potential difference between the source electrode voltage Vs and the counter electrode voltage Vcom. The transparent light intensity from the backlight disposed on the back surface is changed to display the image via the polarizing plate disposed in the vertical direction of the liquid crystal layer.

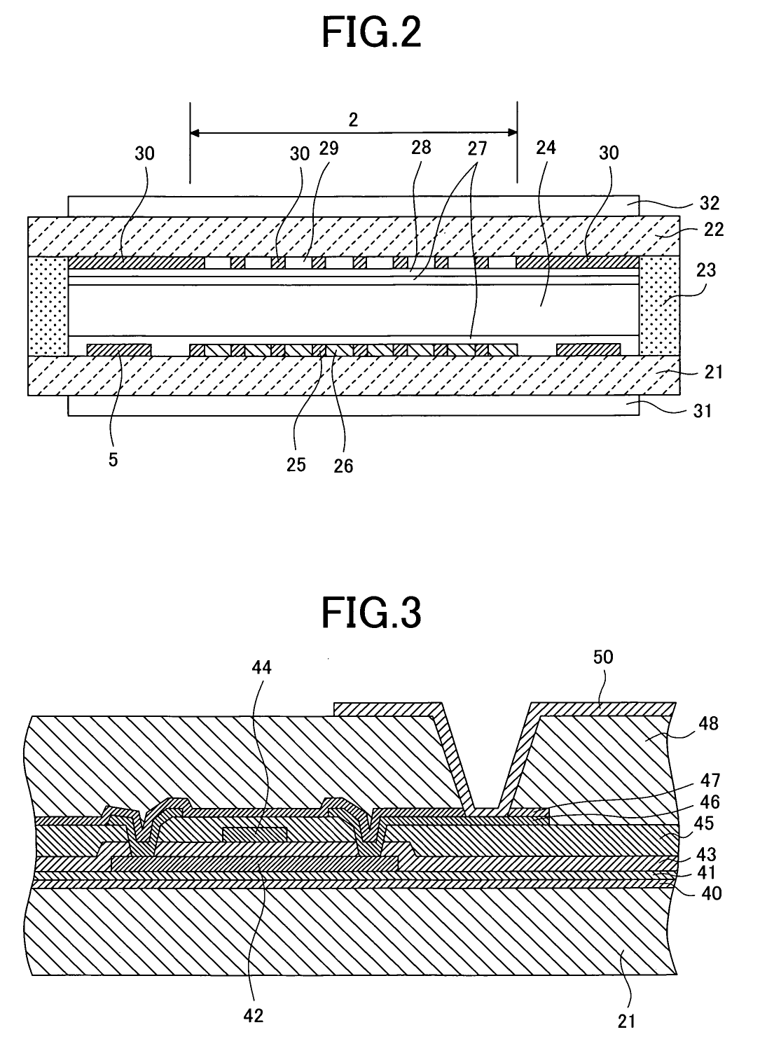

FIG. 2 is a sectional view of the liquid crystal display device. Referring to FIG. 2, a liquid crystal layer 24 is interposed between the TFT substrate 21 and the color filter substrate 22, and is sealed with a sealing member 23.

The pixels which include TFT portions 25 and pixel electrode portions 26 are formed in the effective screen 2 on the TFT substrate 21. The gate driver 5 is formed with the TFT in the region inside the sealing member 23 and outside of the effective screen 2. The TFT of the gate driver is formed through the same process for forming the TFT of the pixel portion simultaneously. An orientation film 27 which covers the pixel electrodes 26 is formed to orient the liquid crystal toward the specific direction. The orientation film 27 determines the orientation direction by rubbing the surface with the fiber-like substance, which may generate the static charge as one of the causes to destroy the TFT of the driver circuit.

The color filters 29, black matrixes 30, a counter electrode 28 formed of the transparent conductive film, and the orientation film 27 are sequentially formed on the color filter substrate 22. The color filters 29 of red, green and blue are sequentially arranged to form the color image. The black matrix 30 is inserted between the adjacent color filters 29 for sharpen the image contrast. The black matrix 30 covers the periphery of the effective screen to protect the TFT for the drive circuit formed around the effective screen from the external light such that no malfunction occurs.

The liquid crystal layer 24 is oriented by the orientation films 27 formed on the TFT substrate 21 and the color filter substrate 22, respectively. The voltage applied to the portion between a pixel electrode 50 formed in the pixel portion of the TFT substrate 21 and the counter electrode 28 formed on the color filter substrate 22 changes the direction of the liquid crystal molecules. When the light from the backlight is modulated, the image is formed. The light from the backlight is required to be polarized so as to allow the liquid crystal to modulate the light. The light from the backlight is polarized into the linear polarized light by a lower polarization plate 31, and further analyzed by an upper polarization plate 32 such that the image formed by the liquid crystal is visibly observed.

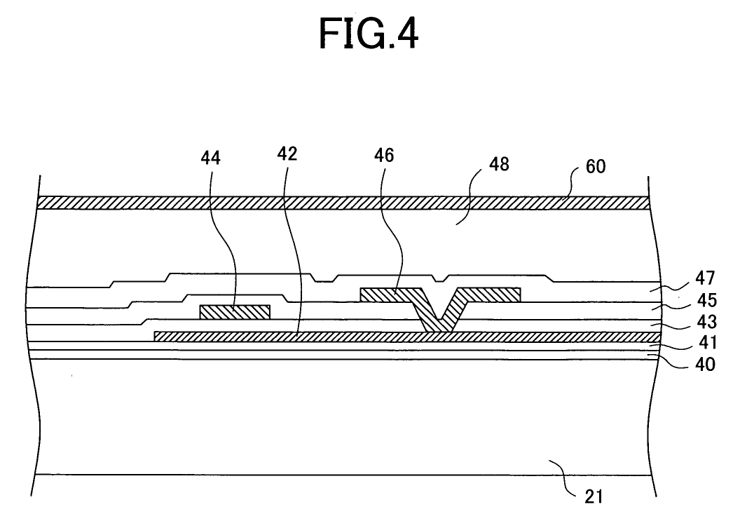

FIG. 3 is a sectional view of the pixel portion of the liquid crystal display device. Referring to FIG. 3, a first base film 40 formed of SiN and a second base film 41 formed of SiO₂ are formed on the glass substrate 21 for the purpose of protecting the semiconductor layer from impurities contained in the glass. A semiconductor film 42 is formed on the second base film 41. The semiconductor film 42 is first coated with a-Si film through the CVD process and the like, and is transformed into the polysilicon semiconductor film 42 by irradiating the excimer laser to the a-Si film. A gate insulation film 43 as SiO₂ is formed on the semiconductor film 42.

A gate electrode 44 is formed on the gate insulation film 43 to dope the impurities to the semiconductor layer through the ion implantation while allowing the gate electrode 44 to serve as the mask such that the portion of the semiconductor film 42 other than the one below the gate electrode 44 is transformed into the n-type semiconductor or p-type semiconductor. Referring to FIG. 3, the doped portion of the semiconductor film 42 becomes the source portion or the drain portion. Meanwhile, the semiconductor below the gate electrode 44 forms the channel portion of the TFT. The gate electrode 44 is formed simultaneously with formation of the scanning signal line 7.

An S/D layer 46 (source electrode or drain electrode) is formed of such metal as Al on an interlayer insulation film 45 formed on the semiconductor layer. The S/D layer 46 is formed simultaneously with formation of the data signal line 8. An inorganic passivation film 47 is formed of SiN for covering the S/D layer 46 so as to protect the TFT portion 25. An organic passivation film 48 with its thickness as large as approximately 2.5 μm is formed on the inorganic passivation film 47. This makes it possible not only to protect the TFT portion 25 but also to flatten the pixel portion. An ITO as the pixel electrode 50 is formed on the organic passivation film 48. The ITO is used for forming the pixel electrode 50 as an example, and the other transparent conductive film may be used for forming the pixel electrode 50. The orientation films 27 are formed on the pixel electrode 50 as shown in FIG. 2.

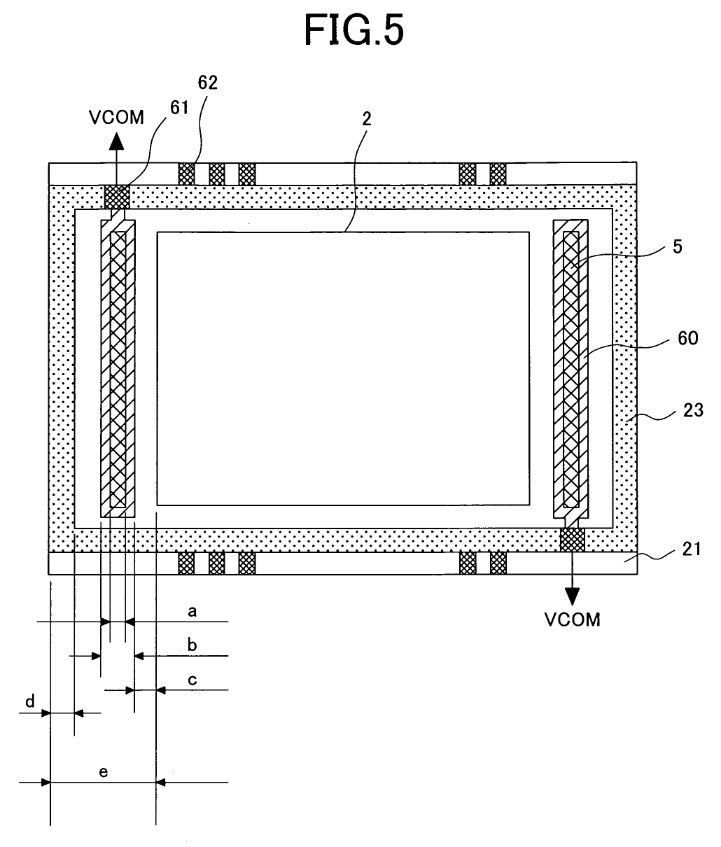

FIG. 4 is a sectional view showing the TFT formed in the gate driver circuit 5. The basic structure is the same as that of the TFT for the pixel portion shown in FIG. 3 as they are simultaneously formed. Referring to FIG. 4, the first base film 40, the second base film 41 and the semiconductor film 42 are sequentially formed on the glass substrate likewise the pixel portion. The a-Si semiconductor film is transformed into the polysilicon through the laser irradiation as described referring to FIG. 3. The semiconductor film 42 shown in FIG. 4 is used not only for the TFT portion but also for the wiring. The impurities are doped to the portion other than the gate electrode 44 through the ion implantation to sufficiently apply conductivity to the semiconductor film 42.

Likewise the pixel electrode portion, the gate insulation film 43, the gate electrode 44, the interlayer insulation film 45, the S/D electrode 46, the inorganic passivation film 47 and the organic passivation film 48 are formed on the semiconductor film 42. The aforementioned layers are formed simultaneously with formation of the TFT in the pixel portion. The respective thicknesses and operations are the same as those of the TFT in the pixel portion as described above.

In the present invention, a static charge shield conductive film 60 is formed on the organic passivation film 48. The constant voltage is applied to the static charge shield conductive film 60 to protect the TFT of the gate driver circuit portion from the external static charge, noise and the like. The static charge shield conductive film 60 has the width larger than that of the gate driver circuit 5 so as to entirely cover the gate circuit portion. As the wide area is covered with the conductive film, short-circuit with the conductive film at the lower portion, for example, the S/D wiring 46 may occur. However, the organic passivation film 48 with the large thickness, and the inorganic passivation film 47 are formed below the static charge shield conductive film 60 to avoid the risk of short-circuit. The organic passivation film 48 may be formed of the acrylic resin, siloxane rein and the like, and the inorganic passivation film 47 may be formed of SiN.

In the embodiment, the ITO is used for forming the static charge shield conductive film 60. The ITO allows direct use of the pixel electrode 50 which is employed for the pixel portion. Accordingly, both the pixel portion and the gate driver circuit 5 may be formed in the same process, thus suppressing the increase in the manufacturing cost even if the static shield conductive film 60 is formed.

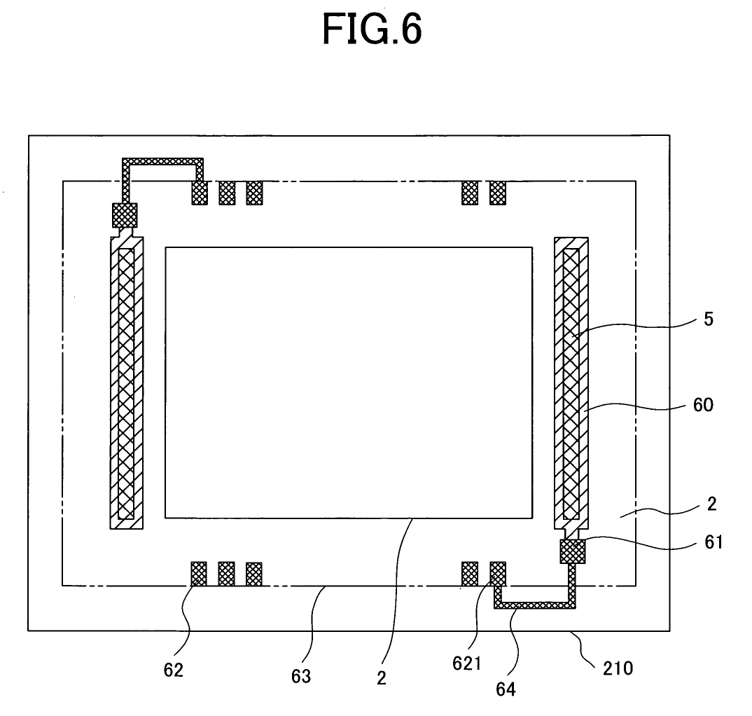

Another problem in the formation of the static shield conductive film 60 is that how and what kind of potential is applied. FIG. 5 is a plan view schematically showing the TFT substrate 21 of the liquid crystal display device. In the embodiment, the common potential is applied by connecting the static charge shield conductive film 60 to a common pad 61 for connection with a common electrode formed in the sealing portion 23. Referring to FIG. 2, the common potential is applied to the counter electrode 28 formed on the color filter substrate 22. The common potential is applied from a terminal 62 of the TFT substrate 21 via the common pad 61. The common pad 61 is connected to the terminal 62 on the TFT substrate 21 to which the common potential is applied, which is not shown in FIG. 5.

As shown in FIG. 5, the gate driver circuits 5 are formed with the TFTs at both sides of the effective screen 2. The static charge shield conductive film 60 is formed to cover the gate driver circuit 5. The static shield conductive film 60 is connected to the common pad 61 so as to receive application of the same common potential as the one applied to the counter electrode 28. The effective screen 2 and the gate driver circuits 5 are sealed inside the sealing member 23. The terminals 62 are formed outside the sealing member 23.

The configuration around the gate driver will be described hereinafter. Referring to FIG. 5, the width a of the gate driver circuit 5 is 200 μm, and the width b of the static charge shield conductive film 60 which covers the gate driver circuit 5 is 400 μm as shown in FIG. 5. As a result, the static charge shield conductive film 60 each width of 100 μm is formed at both sides of the gate driver circuit 5 so as to be sufficiently shielded. The distance c between the side of the effective screen 2 and the adjacent side of the static charge shield conductive film 60 is 100 μm. The width d of the sealing member is 1.5 mm. The distance between the side of the effective screen 2 and the outer side of the sealing member, that is, the outer side of the TFT substrate 21 is in the range from 2.0 to 2.5 mm. As the gate driver circuit 5 formed of the TFT is formed on the TFT substrate 21, the frame portion outside the effective screen may be made extremely small. The increase in the frame portion resulting from formation of the static charge shield conductive film 60 becomes as small as 200 μm.

As described referring to FIG. 5, after the liquid crystal display device is produced, the common voltage applied to the counter electrode 28 formed on the color filter substrate 22 may be supplied to the static charge shield conductive film 60 via the common pad 61. However, in the step for manufacturing the TFT substrate 21, the common voltage cannot be supplied to the static charge shield conductive film 60 from the color filter substrate 22. Meanwhile, in the step for manufacturing the TFT substrate 21, the static charge is generated by rubbing of the orientation film 27. Accordingly, protection of the gate driver circuit 5 is highly required.

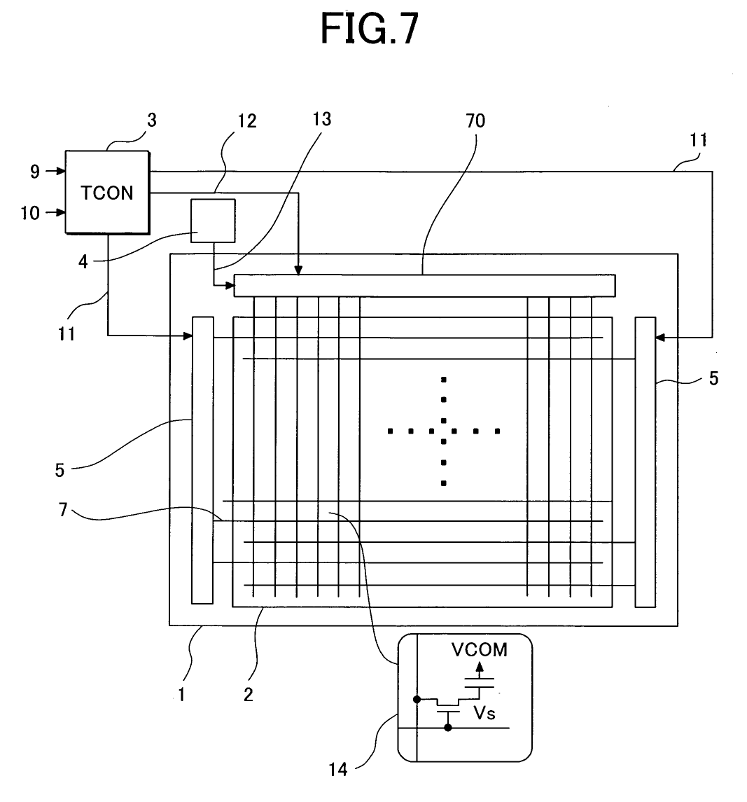

FIG. 6 is a plan view schematically showing the TFT substrate 21 in the manufacturing step. Referring to FIG. 6, a TFT base plate 210 before cutting is cut along a cut line 63 to form the TFT substrate 21. The static charge shield conductive film 60 is connected to the common pad 61. The common pad 61 is further connected to an earth terminal 621 to which the constant potential such as the earth potential is applied in the manufacturing process via the earth connection line 64. The static charge shield conductive film 60 connected to the earth terminal 621 receives application of the constant potential such as the earth potential to protect the gate driver circuit 5 from the static charge. The earth connection line 64 is then cut along the cut line 63 before forming the TFT substrate. After cutting the earth connection line 64, the common pad 61 is connected to the common potential.

In the present invention, the gate driver circuit 5 is protected by the static charge shield conductive film 60 to which the constant potential such as the earth potential is applied in the manufacturing process. After the liquid crystal display device is produced, the gate driver circuit 5 may also be protected by the static charge shield conductive film 60 to which the common potential is applied. Accordingly, the gate driver circuit 5 may be prevented from being destroyed in the manufacturing process. After the liquid crystal display device is produced, malfunction of the gate driver circuit 5 due to the external noise may also be prevented. As the influence of the external noise may be suppressed, the Vth does not have to be increased for preventing the noise to the TFT, thus realizing the high-speed operation.

### Second Embodiment

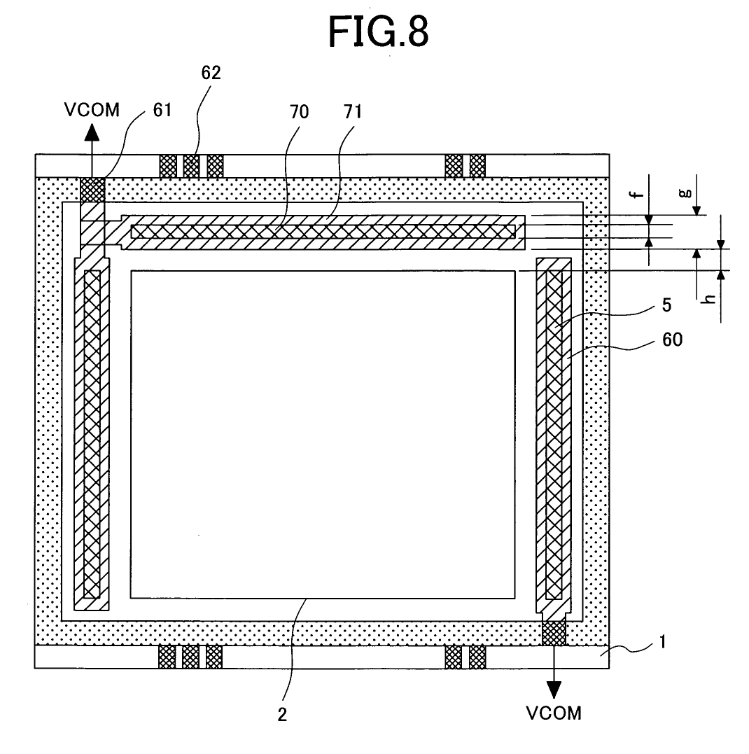

FIG. 7 shows a second embodiment of the present invention which is different from the first embodiment in that a data driver circuit 70 is formed on the TFT substrate 21 with the TFT in addition to the gate driver circuit 5. Referring to FIG. 7, the control IC 3 outputs the data driver control signal set 12 to the data driver circuit 70 formed with the TFT. The data driver control signal set 12 includes the display data, the output signal which defines the output timing of the tone voltage based on the display data, the AC signal which determines the polarity of the source voltage, and the clock signal in synchronization with the display data. Other operations are the same as those described referring to FIG. 1.

FIG. 8 is a plan view schematically showing the TFT substrate 21 of the liquid crystal display device according to the second embodiment. The data driver circuit 70 formed with the TFT is covered with a static charge shield conductive film 71 for the data driver. The static charge shield conductive film 71 for the data driver is conducted with the static charge shield conductive film 60 for the gate driver, and receives application of the common voltage via the common pad 61.

The configuration of the portion around the static charge shield conductive film 71 for the data driver will be described. As the data driver circuit 70 has the size larger than that of the gate driver circuit 5, the width f is approximately 500 μm. The width g of the static charge shield conductive film 71 for the data driver is 700 μm. The distance h between the static charge shield film 71 for the data driver and the adjacent side of the effective screen 2 is 200 μm. Other dimensions are the same as those of the portion around the gate driver circuit 5. The distance between the side of the effective screen 2 and the side of the TFT substrate may be in the range from 2.3 mm to 2.8 mm. In this case, the area of the frame portion may be significantly small compared with the case where the IC chip is externally provided.

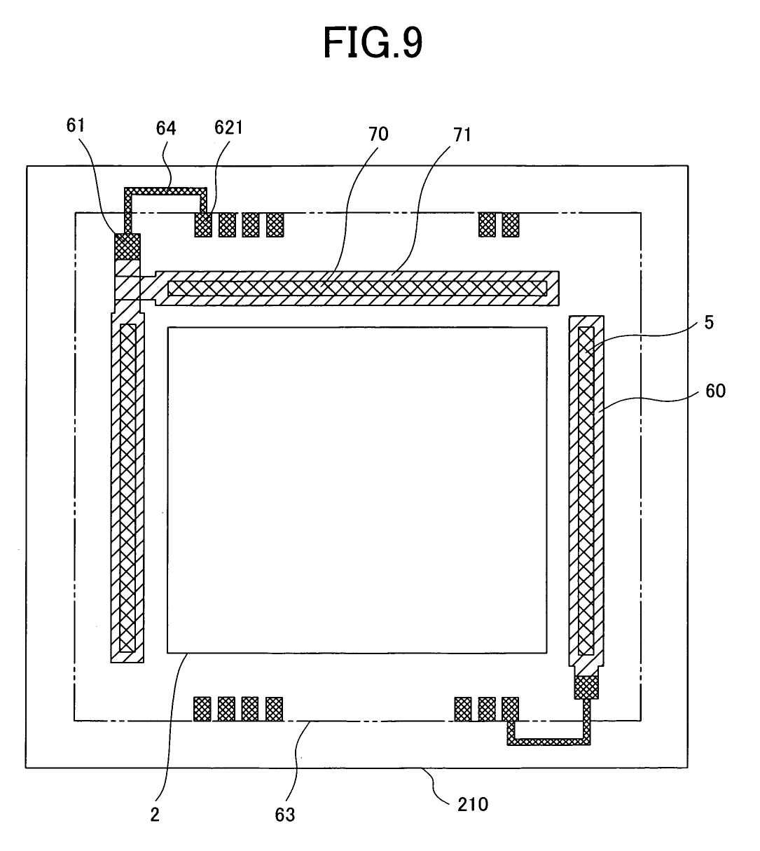

FIG. 9 is a view showing the step in the middle of the TFT substrate manufacturing according to the second embodiment. Referring to FIG. 9, the static charge shield conductive film 71 for the data driver is conducted with the static charge shield conductive film 60 for the gate driver so as to be connected to the earth terminal 621 via the common pad 61 and the earth connector line 64. This makes it possible to protect the data driver from the static charge in the manufacturing step. The other structures are the same as those described referring to FIG. 6.

In the embodiment where the data driver circuit 70 is formed on the TFT substrate 21 with the TFT, the TFT may be prevented from being destroyed in the manufacturing step. After producing the liquid crystal display device, the influence of the noise may be suppressed. As suppression of the influence of the noise may decrease the Vth of the TFT, the high-speed TFT response may be obtained.

### Third Embodiment

The first and the second embodiments provide the liquid crystal display device for forming color images using the color filters 29 as shown in FIG. 2. Although the aforementioned process has been widely employed at present, there is a disadvantage of the low efficiency for using the backlight. In the case where the red image is formed, only the light passing through the red filter may be used while blocking the green and blue components of the backlight.

Meanwhile in the so called field sequential mode, the single frame time is divided into three field times to form the red, green and blue images, respectively. In the mode, the backlight of the desired color is illuminated to be displayed, thus reducing the power consumption of the backlight, that is, the display device.

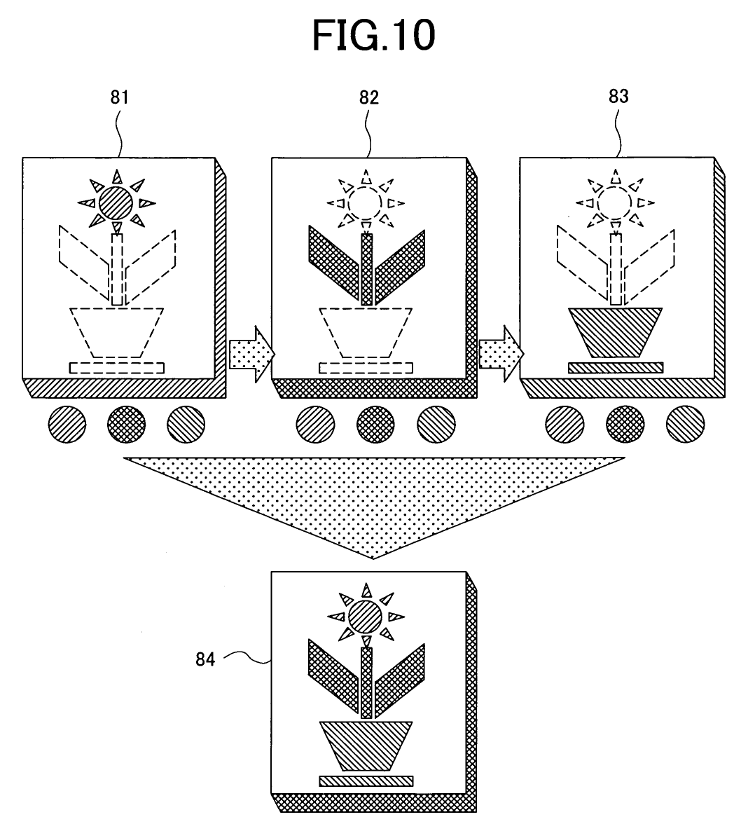

FIG. 10 illustrates the principle of the field sequential mode. Referring to FIG. 10, assuming that an image of a potted plant 84 having the red, green and blue colors is displayed, an image of a flower 81 corresponding to the red color is displayed initially for a predetermined time period. Then an image of a stem and leaves 82 corresponding to the green color is only displayed for the next predetermined time period. Then an image of a pot 83 corresponding to the blue color is only displayed for further the predetermined time period. Due to persistence of vision, the viewer recognizes the image 84 formed by combining the three colors. The backlight employs red, green and blue LEDs such that the desired color is displayed by illuminating the corresponding LED.

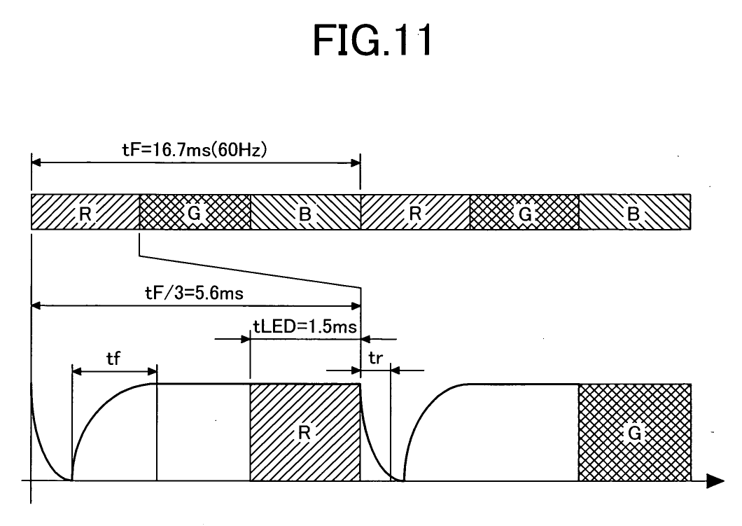

FIG. 11 is a view which illustrates the operation of the liquid crystal display device in the field sequential mode. The single frame time tF is set to 16.7 ms. Each time obtained by dividing the frame time into three fields is 5.6 ms. The image signal for displaying the red component is added to the pixel in the first field. Referring to FIG. 11, after the elapse of a predetermined time period from the liquid crystal rise-up time tf, the red LED is illuminated for the time tLED of 1.5 ms. Thereafter, the image signal indicating the red component and the red LED are turned off simultaneously. The time for allowing the liquid crystal to be restored is designated as tr. The same operations are performed for displaying those colors of green and blue. Each of the backlights for the respective colors is illuminated only for 1.5 ms in the single frame time of 16.7 ms. This may considerably reduce the power consumption of the backlight.

The field sequential mode as described above requires switching of the image signal at the speed three times higher than the one in the liquid crystal display device in the generally employed color filter mode. The display of the image signal at the speed three times higher may impose the burden on the driver circuit to require the TFT to be operated at high speeds. Meanwhile, the threshold voltage Vth of the TFT is required to be increased for preventing the malfunction of the driver circuit due to the static charge noise. However, the increase in the Vth fails to allow the TFT to be operated at higher speeds. The external noise may be reduced by applying the present invention to the liquid crystal display device in the field sequential mode. If the influence of the external noise is reduced, the threshold voltage Vth of the TFT may be decreased, thus allowing the drive circuit to respond at higher speeds. The present invention is effective particularly for the liquid crystal display device in the field sequential mode.

### Fourth Embodiment

The first to the third embodiments represent the example for applying the present invention to the liquid crystal display device. However, the present invention may be applied not only to the liquid crystal display device but also to the other display device using the TFT, for example, the organic EL display device. In the organic EL display device, the TFT is used as the switching element for the respective pixels, and the gate driver circuit, the data driver circuit and the like are formed on the same substrate together with the pixels with the TFT. Accordingly, the structures described in the first to the third embodiments may be applied to the organic EL display device.

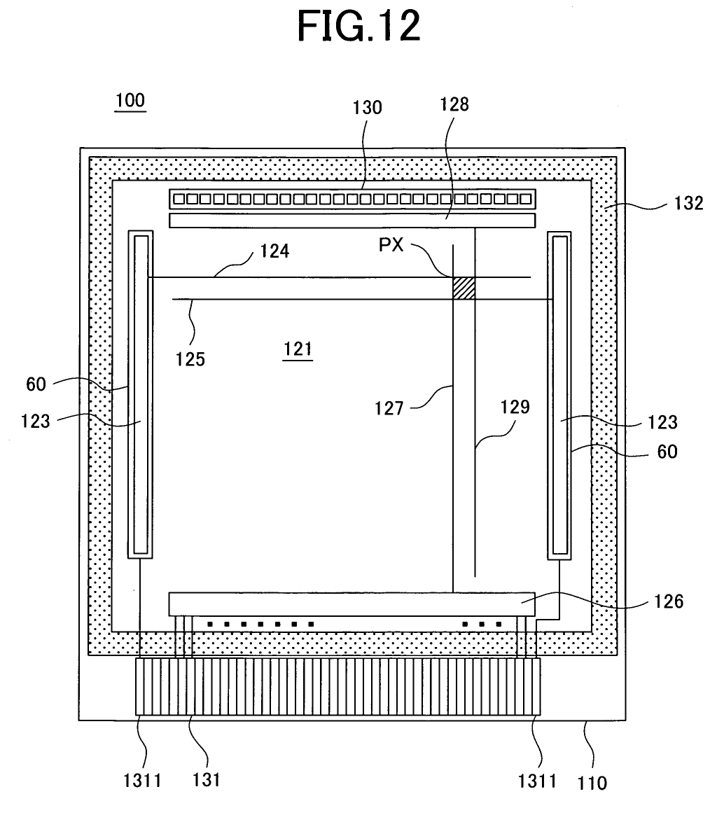

FIG. 12 is a general view of an organic EL display device 100. After a substrate 110 is produced, the organic EL display device 100 is airtight sealed with a back glass (not shown) with the desiccating agent (not shown) to protect the organic EL layer from water content. FIG. 12 is a plan view seen from above showing the substrate 110 before the back glass is attached. A display region 121 is formed on the large center portion of the substrate 110. Gate driver circuits 123 are disposed at both sides of the display region. Gate signal lines extend from the respective gate driver circuits 123. The gate signal line 124 extending from the left gate driver circuit 123 and the gate signal line 125 extending from the right gate driver circuit 123 are alternately arranged.

A data driver circuit 126 is disposed at the lower side of the display region 121. A data signal line 127 extends from the data driver circuit to the display region 121. A current supply bus bar 128 is disposed at the upper side of the display region 121, from where a current supply line 129 extends to the display region 121.

The data signal lien 127 and the current supply line 129 are arranged alternately to form the single pixel PX together with the gate signal lines 124 and 125.

A contact hole set 130 is formed at the upper side of the display region to electrically couple the upper electrode of the organic EL layer formed on the entire area of the display region with the wiring which extends to the terminal, and is formed below the insulation film. A sealing member 132 is formed to enclose the display region 121, the gate driver circuits 123, the data driver circuit 126, and the current supply bus bar 128 where the portion serving as the frame for sealing the substrate 110 with the back glass is sealed. A terminal 131 is formed on the substrate 110 outside the sealing member, from where the signal or the current is supplied to the gate driver circuits 123, the data driver circuit 126, the current supply bus bar 128 and the like.

Referring to FIG. 12, the gate driver circuits 123 at both sides of the display region 121 are covered with the static charge shield conductive films 60. The respective configurations of the gate driver circuit 123 and the static charge shield conductive film 60 are the same as those of the liquid crystal display device as shown in FIG. 5. The constant potential is applied to the static charge shield conductive film 60 from a terminal 1311. The constant potential may be selected from the voltage of the upper electrode, the voltage of the lower electrode for applying the voltage to the organic EL layer, or the frame potential of the display device.

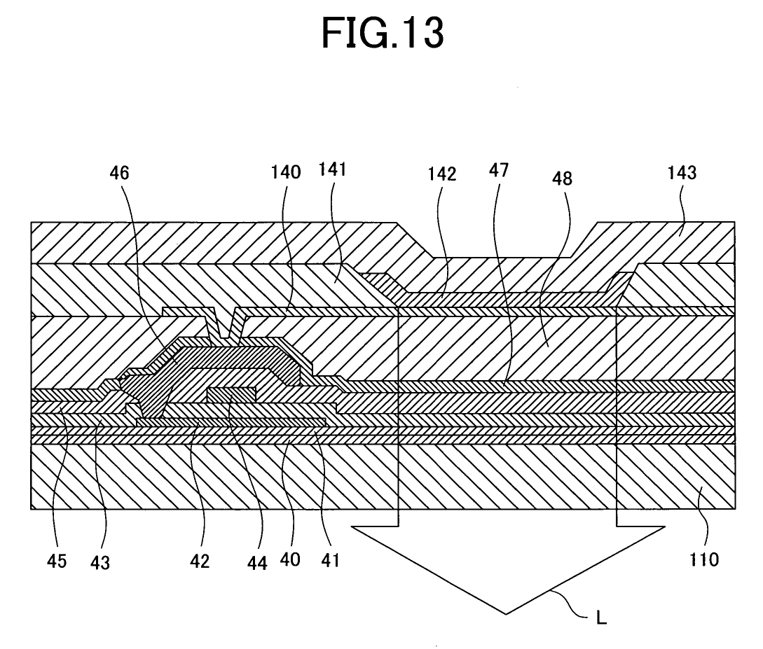

FIG. 13 is a sectional view of the pixel portion PX shown in FIG. 12. FIG. 13 represents the organic EL display device of bottom emission type for radiating the light to the transparent substrate side. Likewise the liquid crystal display device, the organic EL display device also employs the TFT as the switching element. The TFT has the same structure as the one of the liquid crystal display device as shown by the sectional view of FIG. 3. That is, the first base film 40, the second base film 41, the semiconductor layer 42, the gate insulation film 43, the gate electrode 44, the interlayer insulation film 45, the source/drain electrode 46, the inorganic passivation film 47, and the organic passivation film 48 are sequentially formed on the glass substrate 110. The process for forming the respective films and the operations thereof are the same as those described referring to FIG. 3.

In the liquid crystal display device, the pixel electrode 50 as ITO is formed on the organic passivation film 48. Meanwhile, in the organic EL display device, the lower electrode 140 of the organic EL layer 142 is formed. In this case, the lower electrode 140 serves as the positive electrode. As the lower electrode 140 is formed as the ITO, the manufacturing step up to the process for forming the ITO is the same as the one in the case of the liquid crystal display device as described referring to FIG. 3. Likewise the case of the liquid crystal display device, the static charge shield conductive film 60 is formed on the gate driver circuit simultaneously with formation of the ITO used as the lower electrode (positive electrode).

In the organic EL display device, a bank 141 for separating the respective pixels is formed after the formation of the lower electrode 140. The bank 141 may be formed of the acrylic resin, the siloxane resin, the polyimide and the like. However, the material similar to the one for forming the organic passivation film 48 has been generally employed for forming the bank 141. A through hole is formed in the bank 141 by etching the light emission portion to be formed as the organic EL layer 142. Then the organic EL layer 142 is formed in the through hole by performing the vapor deposition. The organic EL layer 142 includes five layers, that is, an electron implantation portion, an electron transfer portion, a light emission portion, a hole transfer portion and a hole implantation portion each having a thickness in the range from 10 nm to 50 nm approximately. The upper electrode 143 as Al is formed on the organic EL layer 142. The light emitted from the organic EL layer 142 proceeds toward the glass substrate 110 (bottom emission). The light proceeding toward the upper electrode 143 is reflected thereby to proceed toward the glass substrate 110 (bottom emission).

In the embodiment, the gate driver circuit 123 is formed on the substrate 110 with the TFT. The TFTs of both the gate driver portion and the pixel portion are simultaneously formed with the same process. As described referring to FIG. 13, the TFT of the pixel portion in the organic EL display device has the same structure as that of the liquid crystal display device. Accordingly, the TFT structure of the gate driver circuit in the organic EL display device is the same as that of the liquid crystal display device as shown in FIG. 4. The static charge shield conductive film 60 shown in FIG. 4 is formed in the same process for forming the pixel electrode 50 of the liquid crystal display device. The static charge shield conductive film 60 shown in FIG. 4 is formed with the same process for forming the pixel electrode 50 in the liquid crystal display. Meanwhile, it is formed with the same process for forming the lower electrode 140 of the organic EL display device. However, the final structure is the same as that of the liquid crystal display device.

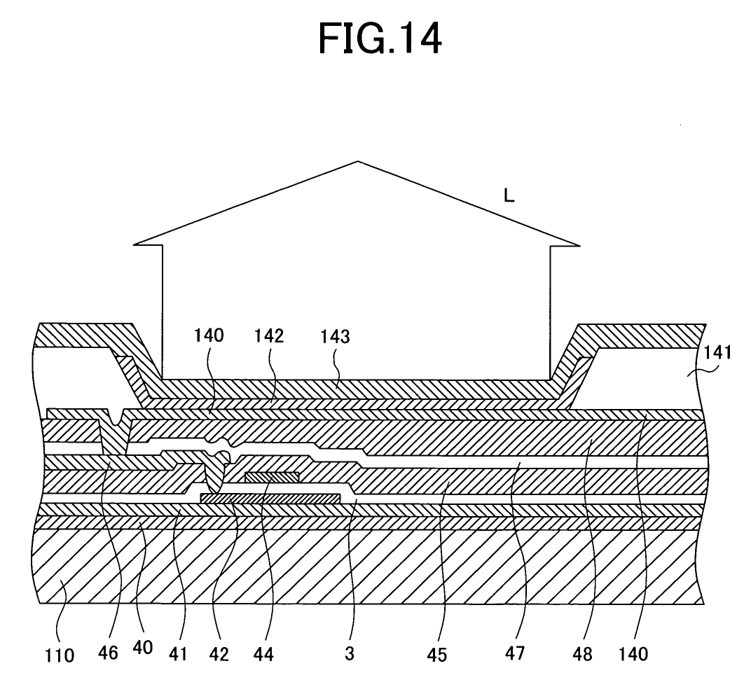

FIG. 14 is a sectional view of the pixel portion PX shown in FIG. 12 with the top emission type. The TFT portion of the pixel with the top emission type has basically the same structure as that of the TFT portion with the bottom emission type. In case of the top emission type, the lower electrode 140 is formed of the metal with the high reflectance such as Al. In the aforementioned case, the lower electrode 140 serves as the negative electrode. After forming the lower electrode 140, the bank 141 for separating the pixels is formed of the organic resin. The through hole is formed by etching the portion as the light emitting portion to be coated with the organic EL film.

The organic EL layer 142 is formed on the lower electrode 140 in the through hole of the bank. The organic EL layer 142 generally has a five-layer structure including the electron implantation portion, the electron transfer portion, the light emitting portion, the hole transfer portion and the hole implantation portion layered from the lower electrode 140. The respective thicknesses of the aforementioned layers are in the range from 10 nm to 60 nm. The transparent metal oxide conductive film, that is, ITO coats the organic EL layer 142 as the upper electrode 143. The ITO as the upper electrode 143 serves as the positive electrode. In case of the top emission type, the emission region may be widened to the upper portion of the TFT to be advantageous in view of the brightness.

The TFT structure of the top emission type is the same as that of the bottom emission type, that is, the liquid crystal display device. Accordingly, the TFT of the gate driver circuit has the similar structure to that of the liquid crystal display device as shown in FIG. 4. However, in case of the top emission type, the ITO is formed in the final step. This makes it possible to dispose the organic resin for forming the bank between the ITO formed of the TFT and the static charge shield conductive film 60 and the source/drain electrode 46 of the TFT in addition to the inorganic passivation film 47 and the organic passivation film.

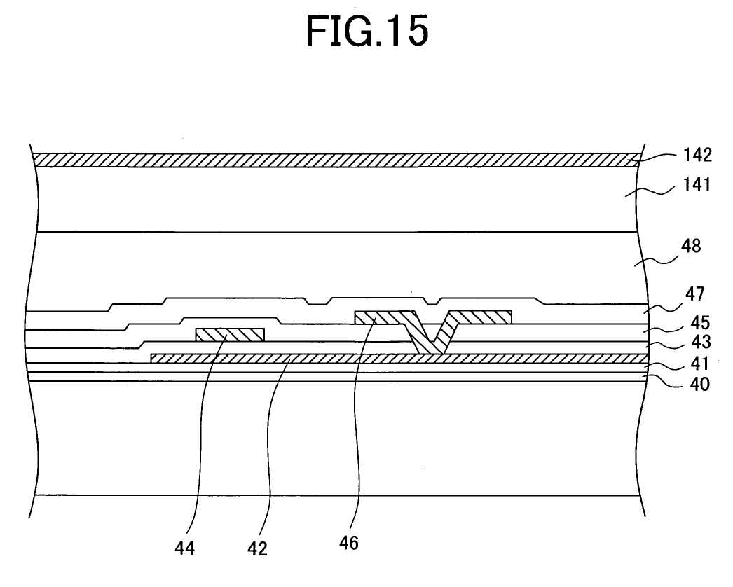

FIG. 15 shows the aforementioned state, that is, the resin for forming the bank 141 is layered on the source/drain electrode 46 in addition to the inorganic passivation film 47 and the organic passivation film 48. The thickness of the organic passivation film 48 is as large as approximately 2.5 μm, and the bank has substantially the same thickness. This makes it possible to form the organic film with the total thickness of 5 μm on the TFT. The thick film thickness of 5 μm further improves the insulation reliability between the wiring of the TFT such as the source/drain electrode and the static charge shield conductive film 60 to be considerably high. The floating capacitance which exists between the TFT and the static charge shield conductive film 60 may reduce the operation speed of the circuit. However, as the organic resin film is structured to have the double-layer to be sufficiently thick, the floating capacitance may be reduced. The organic resin has the relative permittivity of approximately 3.5, which is sufficiently smaller than that of the inorganic insulation film such as SiN of approximately 8. The increase in the thickness of the organic resin may give a great influence to the reduction of the floating capacitance.

What is claimed is:

1. A display device in which a thin film transistor and a pixel portion including a pixel electrode are arranged in a matrix state on an image forming portion of a substrate, and a gate driver circuit including the thin film transistor is formed on the substrate outside the image forming portion,
wherein metal oxide conductive films which interpose an insulation member are formed on the gate driver circuit, and a constant voltage is applied to the metal oxide conductive films.

2. The display device according to claim 1, wherein the metal oxide conductive film is formed simultaneously with formation of the pixel electrode.

3. The display device according to claim 1, wherein the metal oxide conductive film is formed of an ITO.

4. The display device according to claim 1, wherein the gate driver circuits are formed at both sides of the image forming portion.

5. The display device according to claim 1, wherein the metal oxide conductive film partially extends to an end portion of the substrate.

6. A display device in which a thin film transistor and a pixel portion including a pixel electrode are arranged in a matrix state on an image forming portion of a substrate, and a gate driver circuit including the thin film transistor and a data driver circuit including the thin film transistor are formed on the substrate outside the image forming portion, wherein metal oxide conductive films which interpose an insulation member are formed on the gate driver circuit and the data driver circuit, and a constant voltage is applied to the metal oxide conductive films.

7. The display device according to claim 6, wherein the metal oxide conductive film partially extends to an end portion of the substrate.

8. A liquid crystal display device in which a thin film transistor and a pixel portion including a pixel electrode are arranged in a matrix state on an image forming portion of a TFT substrate, a gate driver circuit including the thin film transistor is formed on the TFT substrate outside the image forming portion, and a counter substrate with an electrode to which a common voltage is applied is sealed with the TFT substrate using a sealing member outside the image forming portion,
wherein metal oxide conductive films which interpose an insulation member are formed on the gate driver circuit, and the common voltage is applied to the metal oxide conductive films.

9. The liquid crystal display device according to claim 8, wherein the metal oxide conductive film is conducted with an electrode formed on the counter substrate, to which the common voltage is applied.

10. The liquid crystal display device according to claim 8, wherein the metal oxide conductive film partially extends to an end portion of the TFT substrate.

11. The liquid crystal display device according to claim 8,
wherein the TFT substrate is formed by cutting a base plate which is larger than the TFT substrate in a manufacturing step;
the metal oxide conductive film partially extends to the base plate passing the end portion of the TFT substrate before cutting thereof; and
a constant potential is applied to the metal oxide conductive film in the manufacturing step.

12. The liquid crystal display device according to claim 11, wherein the constant voltage is an earth potential.

13. The liquid crystal display device according to claim 8, wherein an organic resin film is formed between a source/drain electrode of the thin film transistor and the metal oxide conductive film.

14. A liquid crystal display device, in which a thin film transistor and a pixel portion including a pixel electrode are arranged in a matrix state on an image forming portion of a TFT substrate, a gate driver circuit including the thin film transistor and a data driver circuit including the thin film transistor are formed on the TFT substrate outside the image forming portion, and a counter substrate with an electrode to which a common voltage is applied is sealed with the TFT substrate using a sealing member outside the image forming portion,
wherein metal oxide conductive films which interpose an insulation member are formed on the gate driver circuit and the data driver circuit, and the common voltage is applied to the metal oxide conductive films.

15. The liquid crystal display device according to claim 14, wherein the metal oxide conductive film partially extends to an end portion of the TFT substrate.

16. An organic EL display device in which a thin film transistor and a pixel portion including an organic EL light emission portion are arranged in a matrix state on an image forming portion of a substrate, and a gate driver circuit including the thin film transistor is formed on the substrate outside the image forming portion,
wherein metal oxide conductive films which interpose an insulation member are formed on the gate driver circuit, and a constant voltage is applied to the metal oxide conductive films.

17. The organic EL display device according to claim 16,
wherein the organic EL display device is of a bottom emission type;
the organic EL light emission portion is formed of a lower electrode, an organic EL film, and an upper electrode; and
the metal oxide conductive film is formed through the same process as that for forming the lower electrode.

18. The organic EL display device according to claim 16,
wherein the organic EL display device is of a top emission type;
the organic EL light emission portion is formed of a lower electrode, an organic EL film, and an upper electrode; and
the metal oxide conductive film is formed through the same process as that for forming the upper electrode.

19. The organic EL display device according to claim 16, wherein the insulation member includes an organic resin film.

20. The organic EL display device according to claim 18, wherein the insulation member includes an organic resin film with a double-layer structure.
